(19) United States
(12) Patent Application Publication
(10) Pub. No.: US 2020/0024481 A1
(43) Pub. Date: Jan. 23, 2020

(54) POLISHING LIQUID COMPOSITION

(71) Applicant: Kao Corporation, Tokyo (JP)

(72) Inventors: Haruhiko DOI, Wakayama (JP); Tsubasa OYAMA, Wakayama (JP)

(73) Assignee: Kao Corporation, Tokyo (JP)

(21) Appl. No.: 16/338,402

(22) PCT Filed: Sep. 28, 2017
(86) PCT No.: PCT/JP2017/035258

§ 371 Date: Mar. 29, 2019

(30) Foreign Application Priority Data
Sep. 29, 2016 (JP) 2016-192159
Aug. 24, 2017 (JP) 2017-161436

(51) Int. Cl. C09G 1/02; H01L 21/304; H01L 21/321

(52) U.S. Cl. CPC C09G 1/02; C01F 17/0043; H01L 21/3212; H01L 21/304

(57) ABSTRACT

Provided is a polishing composition capable of improving polishing selectivity and reducing polishing unevenness while increasing polishing rate.

The present disclosure relates to a polishing composition containing: cerium oxide particles A; an oligosaccharide B; and water. The oligosaccharide B contains a saccharide made up of 3 to 5 glucoses linked together. In the oligosaccharide B, a content of a saccharide made up of 8 or more glucoses linked together is 27 mass % or less.

### TECHNICAL FIELD

The present disclosure relates to a polishing composition containing cerium oxide particles, and a method for producing a semiconductor substrate using the same, and a method for polishing a substrate using the same.

### BACKGROUND ART

Chemical mechanical polishing (CMP) is a surface planarization technique that includes bringing a processing surface of a substrate to be polished into contact with a polishing pad, supplying a polishing liquid to a contact part between the substrate and the polishing pad, and moving them relatively. Thereby, unevenness portions on the surface of the substrate can be reacted chemically and removed mechanically.

The CMP technique is presently essential for planarization of interlayer insulating films, formation of a shallow trench isolation structure (hereinafter, also referred to as an “element isolation structure”), formation of plugs and buried metal wiring, etc., in the production process of semiconductor elements. In recent years, multilayering and higher definition of semiconductor elements have progressed rapidly, and further improvements in yield and throughput of the semiconductor elements have been demanded. Accordingly, in the CMP processes, a higher polishing rate with no polishing flaws has been demanded. For example, in the formation process of the shallow trench isolation structure, it is desired to improve polishing selectivity of a polishing stopper film (e.g., silicon nitride film) with respect to a film to be polished (e.g., silicon oxide film) (in other words, selectivity in polishing that allows the polishing stopper film to be less likely to be polished than the film to be polished), along with an improvement in the polishing rate.

Patent Document 1 discloses, as a polishing agent for forming an element isolation structure, a CMP polishing agent that contains: cerium oxide particles; a dispersant; an additive selected from water-soluble organic low-molecules having an anionic group such as a —COOM group, a phenolic OH group, a —SO₃M group, an −OSO₃H group, a —PO₄M₂ group, or a —PO₃M₂ group (wherein M is H, NH₄, or a metal atom such as Na or K); and water.

Patent Document 2 discloses a polishing agent that contains: (A) oxide fine particles; (B) at least one selected from the group consisting of a monosaccharide, an oligosaccharide made up of 2 to 20 monosaccharides linked together, sugar alcohols of these, and sugar esters of these; (C) a benzotriazole-based compound; and (D) water.

Patent Document 3 discloses a polishing agent that contains: water; cerium oxide particles; saccharides with 140 or less carbon atoms; a nonionic surfactant; and an organic acid.

Patent Document 4 discloses a polishing agent that contains: a water-soluble inclusion compound such as a cyclic oligosaccharide; polishing abrasive grains; and water.

Patent Document 5 discloses a polishing agent that contains: cerium oxide abrasive grains; water; a polysaccharide; and at least one selected from the group consisting of a water-soluble organic polymer and an anionic surfactant.

Patent Document 6 discloses a polishing agent that contains: water; abrasive grains containing a hydroxide of a tetravalent metal element; an α-glucose polymer; and a cationic polymer.

### PRIOR ART DOCUMENTS

### Patent Documents

Patent Document 1: JP 2001-007060 A
Patent Document 2: JP 2004-055861 A
Patent Document 3: JP 2015-129217 A
Patent Document 4: JP 2011-103410 A
Patent Document 5: WO 2010/104085
Patent Document 6: WO 2015/052988

### DISCLOSURE OF INVENTION

### Problem to be Solved by the Invention

Recently, since high integration has progressed in the semiconductor field, wiring becomes complicated and microfabrication is required. Because of this, in the CMP polishing, it is demanded to further improve the polishing selectivity while increasing the polishing rate. Further, although various additives have been studied to improve the polishing selectivity and increase the polishing rate, such additives in polishing compositions sometimes cause polishing unevenness.

The present disclosure provides a polishing composition capable of improving the polishing selectivity and reducing the polishing unevenness while increasing the polishing rate, a method for producing a semiconductor substrate using the same, and a method for polishing a substrate using the same.

### Means for Solving Problem

The present disclosure relates to a polishing composition (hereinafter, also referred to as “polishing composition of the present disclosure”), containing: cerium oxide particles A; an oligosaccharide B; and water, wherein the oligosaccharide B contains a saccharide made up of 3 to 5 glucoses linked together, and in the oligosaccharide B, a content of a saccharide made up of 8 or more glucoses linked together is 27 mass % or less.

The present disclosure relates to a method for producing a semiconductor substrate, including polishing a substrate to be polished using the polishing composition of the present disclosure.

The present disclosure relates to a method for polishing a substrate, including polishing a substrate to be polished using the polishing composition of the present disclosure, wherein the substrate to be polished is a substrate for producing a semiconductor substrate.

### Effects of the Invention

The present disclosure can produce an effect of providing a polishing composition capable of improving the polishing selectivity and reducing the polishing unevenness while increasing the polishing rate.

### BRIEF DESCRIPTION OF DRAWINGS

FIG. 1 is an observation image of a surface of a silicon nitride film after polishing with a polishing composition of Example 1.

FIG. 2 is an observation image of a surface of a silicon nitride film after polishing with a polishing composition of Comparative Example 4.

### DESCRIPTION OF THE INVENTION

The present inventors found as a result of keen studies that, by adding a predetermined oligosaccharide to a polishing composition containing cerium oxide (hereinafter, also referred to as “ceria”) particles as abrasive grains, it is possible to improve the polishing selectivity and reduce the polishing unevenness while increasing the polishing rate. Thus, the present invention has been accomplished.

Specifically, the present disclosure relates to a polishing composition, containing: cerium oxide particles A; an oligosaccharide B; and water, wherein the oligosaccharide B contains a saccharide made up of 3 to 5 glucoses linked together, and in the oligosaccharide B, a content of a saccharide made up of 8 or more glucoses linked together is 27 mass % or less. The polishing composition of the present disclosure can improve the polishing selectivity and reduce the polishing unevenness while increasing the polishing rate.

Although the precise mechanism that can produce the effect of the present disclosure is not clarified, the following are assumed.

In the polishing using polishing compositions containing cerium oxide particles as abrasive grains, generally the composition of a polishing stopper film such as a silicon nitride film becomes almost equal to the composition of a film to be polished such as a silicon oxide film due to hydrolysis by water molecules. Because of this, the polishing stopper film is easily polished by cerium oxide particles. On the other hand, in the polishing using the polishing composition of the present disclosure, a specific oligosaccharide B hydrates with water molecules, and suppresses the hydrolysis of the polishing stopper film such as a silicon nitride film, thereby suppressing the polishing by cerium oxide. Moreover, the polishing composition of the present disclosure containing a specific oligosaccharide B can have a high ability to suppress the polishing with respect to the polishing stopper film such as a silicon nitride film, thereby suppressing the polishing unevenness of the polishing stopper film such as a silicon nitride film.

Note that the present disclosure is not limited to these mechanisms.

The term “polishing selectivity” in the present disclosure is synonymous with a ratio of the polishing rate (polishing rate ratio) for the film to be polished with respect to the polishing rate for the polishing stopper film (the polishing rate for the film to be polished/the polishing rate for the polishing stopper film). High “polishing selectivity” means a high polishing rate ratio.

The “oligosaccharide” is generally categorized between monosaccharide and polysaccharide, and is a generic name for a saccharide containing a small number of monosaccharides linked by glycosidic linkage. The number of monosaccharides (degree of polymerization) constituting the oligosaccharide is, e.g., about 2 to 20.

[Cerium Oxide (Ceria) Particles A]

The polishing composition of the present disclosure contains cerium oxide particles A (hereinafter, also referred to as “particles A” simply) as polishing abrasive grains. The production method, shape and surface condition of the particles A are not particularly limited. Examples of the particles A include colloidal ceria, amorphous ceria, and ceria-coated silica. The colloidal ceria can be obtained through a buildup process by the method described in Examples 1-4 of JP 2010-505735 A, for example. The amorphous ceria can be obtained by baking and pulverizing a cerium compound such as cerium carbonate or cerium nitrate, for example. The ceria-coated silica may be composite particles in which at least part of the surfaces of silica particles are coated with particulate ceria by the method described in Examples 1-14 of JP 2015-063451 A or the method described in Examples 1-4 of JP 2013-119131 A, for example. The composite particles can be obtained by depositing ceria on silica particles, for example. The colloidal ceria is preferred from the viewpoint of improving the polishing rate. The ceria-coated silica is preferred from the viewpoint of reducing residues after polishing. The particles A may be one kind of ceria particles, or a combination of two or more kinds of ceria particles.

The average primary particle diameter of the particles A is preferably 5 nm or more, more preferably 10 nm or more, and further preferably 20 nm or more from the viewpoint of improving the polishing rate, while the average primary particle diameter thereof is preferably 300 nm or less, more preferably 200 nm or less, and further preferably 150 nm or less from the viewpoint of reducing polishing flaws. In the present disclosure, the average primary particle diameter of the particles A is calculated using a BET specific surface area S (m²/g) calculated by a BET (nitrogen adsorption) method. The BET specific surface area can be measured by a method described in the examples.

The particles A may have, e.g., a substantially spherical shape, a polyhedral shape, or a raspberry shape.

When the total content of the particles A, the oligosaccharide B and water is assumed to be 100 mass %, the content of the particles A in the polishing composition of the present disclosure is preferably 0.05 mass % or more, more preferably 0.10 mass % or more, and further preferably 0.20 mass % or more from the viewpoint of increasing the polishing rate and improving the polishing selectivity, while the content thereof is preferably 10.0 mass % or less, more preferably 7.5 mass % or less, further preferably 5.0 mass % or less, still further preferably 2.5 mass % or less, and even further preferably 1.0 mass % or less from the same viewpoint. When the particles A are a combination of two or more kinds of ceria particles, the content of the particles A is a total content thereof.

[Oligosaccharide B]

The polishing composition of the present disclosure contains an oligosaccharide B. It is preferred that the oligosaccharide B contains a saccharide made up of 3 to 5 glucoses linked together, and in the oligosaccharide B, a content of a saccharide made up of 8 or more glucoses linked together is 27 mass % or less, wherein the structure of the oligosaccharide B is not cyclic but linear or branched, from the viewpoint of increasing the polishing rate, improving the polishing selectivity and reducing the polishing unevenness. The linkage of the 3 to 5 glucoses is preferably a glucosidic linkage. The saccharide made up of 3 to 5 glucoses is preferably an active component of the oligosaccharide B. It is preferred that the monosaccharides constituting the oligosaccharide B of the present disclosure, i.e., the constituent units of the oligosaccharide B are, e.g., glucose only, from the viewpoint of increasing the polishing rate, improving the polishing selectivity and reducing the polishing unevenness. The oligosaccharide B may be one kind of oligosaccharide or a combination of two or more kinds of oligosaccharides. In the present disclosure, the “content of a saccharide made up of 8 or more glucoses” is a proportion of the saccharide made up of 8 or more glucoses in the oligosaccharide B.

In the oligosaccharide B, the content of a saccharide having a molecular weight of 15,000 or more is preferably 0 mass % or more, and preferably 10 mass % or less, more preferably 5 mass % or less, and further preferably 4 mass % or less, from the viewpoint of increasing the polishing rate, improving the polishing selectivity and reducing the polishing unevenness.

The oligosaccharide B may be at least one selected from gentiooligosaccharide B1, isomaltooligosaccharide B2, maltooligosaccharide B3, and nigerooligosaccharide B4, from the viewpoint of increasing the polishing rate, improving the polishing selectivity and reducing the polishing unevenness. Among these, the oligosaccharide B is preferably one kind or a combination of two or more kinds selected from gentiooligosaccharide B1, isomaltooligosaccharide B2, and nigerooligosaccharide B4, more preferably at least one of gentiooligosaccharide B1 and isomaltooligosaccharide B2, and further preferably gentiooligosaccharide B1, from the viewpoint of increasing the polishing rate and improving the polishing selectivity.

The gentiooligosaccharide B1 in the present disclosure may be, e.g., a gentiooligosaccharide that contains, as an active component, a linear oligosaccharide made up of 3 to 5 glucoses linked mainly via a ß-1,6-glucosidic linkage, from the viewpoint of increasing the polishing rate and improving the polishing selectivity. Specifically, the gentiooligosaccharide B1 may be a gentiooligosaccharide that contains, as an active component, gentiotriose (trisaccharide), gentiotetraose (tetrasaccharide), or the like. The gentiooligosaccharide B1 can be produced by reacting glucose with ß-glucosidase, for example. The gentiooligosaccharide B1 produced by the method as described above and gentiooligosaccharides B1 on the market may contain components other than the above active component, such as monosaccharides including glucose and fructose, disaccharides such as gentibiose, and saccharides having a degree of polymerization of 6 or more. These other components may be contained in the polishing composition of the present disclosure within a range that does not largely impair the effect of the present disclosure. In the gentiooligosaccharide B1, the content of the saccharide made up of 8 or more glucoses is preferably 27 mass % or less, from the viewpoint of increasing the polishing rate and improving the polishing selectivity.

The isomaltooligosaccharide B2 in the present disclosure may be, e.g., an isomaltooligosaccharide that contains, as an active component, a branched oligosaccharide made up of 3 to 5 glucoses linked via an α-1,4 and/or α-1,6-glucosidic linkage, from the viewpoint of increasing the polishing rate and improving the polishing selectivity. Specifically, the isomaltooligosaccharide B2 may be an isomaltooligosaccharide that contains, as an active component, isomaltotriose (trisaccharide), panose (trisaccharide), or the like. The isomaltooligosaccharide B2 can be produced by a method including: subjecting dextran to acid treatment to selectively decompose linkages other than the α-1,6-glucosidic linkage in the dextran molecule; and reacting the acid-treated dextran solution with endodextranase or endodextranase immobilized on a carrier to cause an enzyme reaction, for example. The isomaltooligosaccharide B2 produced by the method as described above and isomaltooligosaccharides B2 on the market may contain components other than the above active component, such as isomaltose (disaccharide) and saccharides having a degree of polymerization of 6 or more. These other components may be contained in the polishing composition of the present disclosure within a range that does not largely impair the effect of the present disclosure. In the isomaltooligosaccharide B2, the content of the saccharide made up of 8 or more glucoses is preferably 27 mass % or less, from the viewpoint of increasing the polishing rate and improving the polishing selectivity.

The maltooligosaccharide B3 in the present disclosure may be, e.g., a maltooligosaccharide that contains, as an active component, a linear oligosaccharide made up of 3 to 5 glucoses linked via an α-1,4 glucosidic linkage, from the viewpoint of increasing the polishing rate and improving the polishing selectivity. Specifically, the maltooligosaccharide B3 may be a maltooligosaccharide that contains, as an active component, maltotriose (trisaccharide), maltotetraose (tetrasaccharide), or the like. The maltooligosaccharide B3 can be produced by reacting starch with a maltooligosaccharide-forming amylase, for example. The maltooligosaccharide B3 produced by the method as described above and maltooligosaccharides B3 on the market may contain components other than the above active component, such as maltose (disaccharide) and saccharides having a degree of polymerization of 6 or more. These other components may be contained in the polishing composition of the present disclosure within a range that does not largely impair the effect of the present disclosure. In the maltooligosaccharide B3, the content of the saccharide made up of 8 or more glucoses is preferably 27 mass % or less, from the viewpoint of increasing the polishing rate and improving the polishing selectivity.

The nigerooligosaccharide B4 in the present disclosure may be, e.g., a nigerooligosaccharide that contains, as an active component, a branched oligosaccharide made up of 3 to 5 glucoses linked via an α-1,3 and/or α-1,4-glucosidic linkage, from the viewpoint of increasing the polishing rate and improving the polishing selectivity. Specifically, the nigerooligosaccharide B4 may be a nigerooligosaccharide that contains, as an active component, nigerotriose (trisaccharide), nigerosylglucose (trisaccharide), nigerotetraose (tetrasaccharide), nigerosylmaltose (tetrasaccharide), or the like. The nigerooligosaccharide B4 can be produced by reacting a maltose solution (substrate) with a nigerooligosaccharide-forming enzyme, for example. The nigerooligosaccharide B4 produced by the method as described above and nigerooligosaccharides B4 on the market may contain components other than the above active component, such as nigerobiose (disaccharide) and saccharides having a degree of polymerization of 6 or more. These other components may be contained in the polishing composition of the present disclosure within a range that does not largely impair the effect of the present disclosure. In the nigerooligosaccharide B4, the content of the saccharide made up of 8 or more glucoses is preferably 27 mass % or less, from the viewpoint of increasing the polishing rate and improving the polishing selectivity.

The weight average molecular weight of the oligosaccharide B is preferably less than 800, more preferably 750 or less, further preferably 700 or less, and still further preferably 600 or less, while the weight average molecular weight thereof is preferably 300 or more, more preferably 350 or more, and further preferably 400 or more, from the viewpoint of increasing the polishing rate, improving the polishing selectivity and reducing the polishing unevenness. The weight average molecular weight of the oligosaccharide B can be calculated in the same manner as the method for measuring the weight average molecular weight of the compound C, which is described later.

When the total content of the particles A, the oligosaccharide B and water is assumed to be 100 mass %, the content of the oligosaccharide B in the polishing composition of the present disclosure is preferably 0.2 mass % or more, more preferably 0.3 mass % or more, further preferably 0.4 mass % or more, still further preferably 0.5 mass % or more, and even further preferably 0.8 mass % or more from the viewpoint of reducing the polishing unevenness and suppressing the polishing of the polishing stopper film, while the content thereof is preferably 2.5 mass % or less, more preferably 2.0 mass % or less, further preferably 1.5 mass % or less, and still further preferably 1.1 mass % or less from the viewpoint of increasing the polishing rate and improving the polishing selectivity. From the same viewpoint, the content of the oligosaccharide B is preferably 0.1 mass % or more and 2.5 mass % or less, more preferably 0.3 mass % or more and 2.5 mass % or less, further preferably 0.4 mass % or more and 2.0 mass % or less, and still further preferably 0.5 mass % or more and 1.5 mass % or less. When the oligosaccharide B is a combination of two or more kinds of oligosaccharides, the content of the oligosaccharide B is a total content thereof.

When the total content of the particles A, the oligosaccharide B and water is assumed to be 100 mass %, the content of the saccharide made up of 3 to 5 glucoses in the polishing composition of the present disclosure is preferably 0.05 mass % or more, more preferably 0.08 mass % or more, further preferably 0.10 mass % or more, still further preferably 0.12 mass % or more, yet further preferably 0.15 mass % or more, even further preferably 0.25 mass % or more, and still further preferably 0.35 mass % or more from the viewpoint of reducing the polishing unevenness and suppressing the polishing of the polishing stopper film, while the content thereof is preferably 1.0 mass % or less, more preferably 0.7 mass % or less, and further preferably 0.5 mass % or less from the viewpoint of increasing the polishing rate and improving the polishing selectivity.

A ratio B/A of the content of the oligosaccharide B to the content of the particles A in the polishing composition of the present disclosure is preferably 0.01 or more, more preferably 0.1 or more, and further preferably 0.3 or more, while the ratio B/A is preferably 20 or less, more preferably 10 or less, and further preferably 5 or less from the viewpoint of increasing the polishing rate, improving the polishing selectivity and reducing the polishing unevenness.

[Compound C]

The polishing composition of the present disclosure preferably contains a compound C having an anionic group (hereinafter, also referred to as “compound C”) as a polishing aid from the viewpoint of increasing the polishing rate and improving the polishing selectivity. The compound C may be one kind or a combination of two or more kinds.

Examples of the anionic group of the compound C include a carboxylic acid group, a sulfonic acid group, a sulfate group, a phosphate group, and a phosphonic acid group. These anionic groups may take a form of neutralized salts. Examples of a counter ion, when the anionic group takes a form of a salt, include a metal ion, an ammonium ion, and an alkylammonium ion. Among these, the ammonium ion is preferred from the viewpoint of improving the quality of a semiconductor substrate.

The compound C may be at least one selected from a monovalent carboxylic acid, citric acid and an anionic polymer.

Specific examples of the anionic polymer as the compound C include polyacrylic acid, polymethacrylic acid, polystyrene sulfonate, a copolymer of (meth)acrylic acid and monomethoxypolyethylene glycol mono(meth)acrylate, a copolymer of (meth)acrylate having an anionic group and monomethoxypolyethylene glycol mono(meth)acrylate, a copolymer of alkyl(meth)acrylate and (meth)acrylic acid and monomethoxypolyethylene glycol mono(meth)acrylate, alkali metal salts thereof, and ammonium salts thereof. Among these, the compound C is preferably at least one selected from polyacrylic acid and an ammonium salt thereof from the viewpoint of improving the quality of a semiconductor substrate.

When the compound C is an anionic polymer, the weight average molecular weight of the compound C is preferably 1,000 or more, more preferably 10,000 or more, and further preferably 20,000 or more, while the weight average molecular weight thereof is preferably 5,500,000 or less, more preferably 1,000,000 or less, and further preferably 100,000 or less from the viewpoint of increasing the polishing rate and improving the polishing selectivity.

In the present disclosure, the weight average molecular weight can be measured by gel permeation chromatography (GPC) under the following conditions using a liquid chromatograph (L-6000 high-speed liquid chromatograph manufactured by Hitachi, Ltd.).

Detector: Shodex RI, SE-61 differential refractometer detector

Column: G4000PWXL and G2500PWXL (manufactured by TOSHO CORPORATION) connected in series

Eluent a sample was adjusted with 0.2 M phosphate buffer solution/acetonitrile=90/10 (capacity ratio) to have a concentration of 0.5 g/100 mL, and 20 μL of the sample was used.

Column temperature: 40° C.

Flow rate: 1.0 mL/min

Reference polymer: monodispersed polyethylene glycol of known molecular weight

When the compound C is a monovalent carboxylic acid, the compound C may be at least one selected from levulinic acid, propionic acid, vanillic acid, p-hydroxybenzoic acid, and formic acid. It is considered that the polishing composition of the present disclosure containing the monovalent carboxylic acid as the compound C can have favorable storage stability.

The content of the compound C in the polishing composition of the present disclosure is preferably 0.001 mass % or more, more preferably 0.0015 mass % or more, and further preferably 0.0025 mass % or more, while the content thereof is preferably 1.0 mass % or less, more preferably 0.8 mass % or less, and further preferably 0.6 mass % or less from the viewpoint of increasing the polishing rate and improving the polishing selectivity. When the compound C is a combination of two or more kinds, the content of the compound C is a total content thereof.

A ratio (C/A) of the content of the compound C to the content of the particles A in the polishing composition of the present disclosure is preferably 0.0001 or more, more preferably 0.0005 or more, and further preferably 0.001 or more, while the ratio (C/A) is preferably 1 or less, more preferably 0.1 or less, and further preferably 0.01 or less from the viewpoint of increasing the polishing rate and improving the polishing selectivity.

[Water]

The polishing composition of the present disclosure contains water as a medium. The water is preferably ion exchanged water, distilled water, or ultrapure water from the viewpoint of improving the quality of a semiconductor substrate. When the total content of the particles A, the oligosaccharide B, water, and the compound C and undermentioned optional components to be added as needed is assumed to be 100 mass %, the content of water in the polishing composition of the present disclosure may be a remainder after subtracting the contents of the particles A, the oligosaccharide B, the compound C, and the optional components.

[Optional Components]

The polishing composition of the present disclosure may contain optional components such as a pH regulator, a surfactant other than the compound C, a thickener, a dispersant, a rust-preventive agent, a basic substance, and a polishing rate improver within a range that does not impair the effect of the present disclosure. The content of the optional components is preferably 0.001 mass % or more, more preferably 0.0025 mass % or more, and further preferably 0.01 mass % or more from the viewpoint of improving the polishing rate, while the content thereof is preferably 1 mass % or less, more preferably 0.5 mass % or less, and further preferably 0.1 mass % or less from the viewpoint of improving the polishing selectivity.

The pH regulator may be, e.g., an acidic compound or an alkali compound. Examples of the acidic compound include: inorganic acids such as hydrochloric acid, nitric acid and sulfuric acid; and organic acids such as acetic acid, oxalic acid, citric acid and malic acid. Among these, the acidic compound is preferably at least one selected from hydrochloric acid, nitric acid and acetic acid, and more preferably at least one selected from hydrochloric acid and acetic acid from the viewpoint of versatility. Examples of the alkali compound include: inorganic alkali compounds such as ammonia and potassium hydroxide; and organic alkali compounds such as alkylamine and alkanolamine. Among these, the alkali compound is preferably at least one selected from ammonia and alkylamine, and more preferably ammonia from the viewpoint of improving the quality of a semiconductor substrate.

The surfactant other than the compound C may be, e.g., an anionic surfactant or a non-ionic surfactant other than the component C. Examples of the anionic surfactant include alkyl ether acetate, alkyl ether phosphate, and alkyl ether sulfate. Examples of the non-ionic surfactant include non-ionic polymers such as polyacrylamide, and polyoxyalkylene alkyl ether, and polyoxyethylene distyrenated phenyl ether.

In one or more embodiments, the polishing composition of the present disclosure may not substantially contain a non-ionic surfactant. In the present disclosure, “not substantially contain a non-ionic surfactant” means that the content of the non-ionic surfactant in the polishing composition is 0.1 mass % or less. The content of the non-ionic surfactant in the polishing composition of the present disclosure is preferably less than 0.01 mass %, more preferably 0.005 mass % or less, and further preferably substantially 0 mass % from the viewpoint of increasing the polishing rate for a silicon oxide film and improving the polishing selectivity.

In one or more embodiments, the polishing composition of the present disclosure may contain a compound having four or more amino groups.

[Polishing Composition]

The polishing composition of the present disclosure can be produced by a production method including blending a slurry containing the particles A and water, the oligosaccharide B, and as needed, the compound C and the optional components by a known method. For example, the polishing composition of the present disclosure may be a polishing composition produced by blending at least the particles A, the oligosaccharide B and water. In the present disclosure, “blending” includes mixing the particles A, the oligosaccharide B, water, and as needed, the compound C and the other optional components simultaneously or sequentially. The order of mixing is not particularly limited. The blending can be carried out using a mixer such as a homomixer, a homogenizer, an ultrasonic disperser, or a wet ball mill. The blending amount of each component in the production method of the polishing composition of the present disclosure can be the same as the above content of each component in the polishing composition of the present disclosure.

In one or more embodiments, the polishing composition of the present disclosure may be a one-pack type that is put on the market in a state in which all the components are mixed beforehand, or a two-pack type that is mixed in use. The two-pack type polishing composition is separated into a first liquid and a second liquid. For example, the polishing composition may be composed of a first liquid in which the particles A are mixed in water and a second liquid in which the oligosaccharide B is mixed in water, and the first liquid and the second liquid are mixed in use. The first liquid and the second liquid may be mixed before being supplied to the surface of an object to be polished, or they may be separately supplied to the surface of a substrate to be polished and mixed thereon.

The pH of the polishing composition of the present disclosure is preferably 4.0 or more, more preferably 5.0 or more, and further preferably 6.0 or more, while the pH thereof is preferably 9.0 or less, more preferably less than 9.0, further preferably 8.5 or less, and still further preferably 8.0 or less from the viewpoint of increasing the polishing rate and improving the polishing selectivity. The pH of the polishing composition in the present disclosure is a value thereof at 25 C.° measured using a pH meter. Specifically, the pH of the polishing composition in the present disclosure can be measured by a method described in the examples.

The “content of each component in the polishing composition” in the present disclosure refers to the content of the each component at the time the polishing composition is used for polishing. The polishing composition of the present disclosure may be preserved and provided in the form of a concentrate as long as its stability is not impaired. This is preferred because the production and transportation costs can be reduced. The concentrate of the polishing composition of the present disclosure can be diluted appropriately with the above aqueous medium as needed so as to be used in the polishing step. The dilution ratio is preferably 5 to 100 times.

[Film to be Polished]

A film to be polished by the polishing composition of the present disclosure may be, e.g., a silicon oxide film. The polishing composition of the present disclosure can be suitably used in polishing a silicon oxide film in the formation of the element isolation structure of a semiconductor substrate.

[Polishing Liquid Kit]

The present disclosure relates to a polishing liquid kit for producing the polishing composition, the kit composed of a dispersion liquid of the particles A, which is a dispersion liquid containing the particles A held in a container, and the oligosaccharide B, which is held in a container different from the container of the dispersion liquid of the particles A. The polishing liquid kit of the present disclosure can provide a polishing composition capable of improving the polishing selectivity and reducing the polishing unevenness while increasing the polishing rate.

The polishing liquid kit of the present disclosure may be a polishing liquid kit (two-pack type polishing composition) in which a dispersion liquid containing the particles A (first liquid) and a solution containing the oligosaccharide B (second liquid) are stored in a state of not being mixed with each other, and they are mixed in use. Water may be added as needed to the mixture of the first liquid and the second liquid for dilution. The second liquid may contain other components that can be blended in the polishing composition for use in polishing an object to be polished. Examples of the other components that can be blended in the polishing composition include the compound C, an acid, an oxidizer, a heterocyclic aromatic compound, an aliphatic amine compound, and an alicyclic amine compound. The first liquid and the second liquid each may contain optional components as needed. Examples of the optional components include a thickener, a dispersant, a rust-preventive agent, a basic substance, a polishing rate improver, a surfactant, and a macromolecular compound.

[Method for Producing Semiconductor Substrate]

The present disclosure relates to a method for producing a semiconductor substrate (hereinafter, also referred to as “production method of a semiconductor substrate of the present disclosure”), including polishing a film to be polished using the polishing composition of the present disclosure (hereinafter, also referred to as “polishing step using the polishing composition of the present disclosure”). The production method of a semiconductor substrate of the present disclosure can improve the polishing selectivity and reduce the polishing unevenness while increasing the polishing rate in the polishing step, thereby providing an effect of producing a semiconductor substrate with improved substrate quality efficiently.

As a specific example of the production method of a semiconductor substrate of the present disclosure, first, a silicon substrate is exposed to oxygen in an oxidation furnace so as to grow a silicon dioxide layer on its surface, and then a polishing stopper film such as a silicon nitride (Si₃N₄) film or a polysilicon film is formed on the silicon dioxide layer by, e.g., a CVD method (chemical vapor deposition method). Next, a trench is formed using a photolithography technique on the substrate including the silicon substrate and the polishing stopper film that is arranged on one principal surface of the silicon substrate (e.g., a substrate in which a polishing stopper film is formed on a silicon dioxide layer of a silicon substrate). Next, a silicon oxide (SiO₂) film for filling trench (film to be polished) is formed by, e.g., a CVD method using a silane gas and an oxygen gas. Thus, a substrate to be polished in which the polishing stopper film is covered with the film to be polished (silicon oxide film) is obtained. By forming the silicon oxide film, the trench is filled with silicon oxide of the silicon oxide film, and the surface of the polishing stopper film that is opposite to the surface facing the silicon substrate side is covered with the silicon oxide film. The surface of the silicon oxide film thus formed that is opposite to the surface facing the silicon substrate side has a difference in height formed correspondingly to the convexo-concave pattern of the lower layers. Next, the silicon oxide film is polished by the CMP method until at least the surface of the polishing stopper film that is opposite to the surface facing the silicon substrate side is exposed, more preferably until the surface of the silicon oxide film is flush with the surface of the polishing stopper film. The polishing composition of the present disclosure can be used in the polishing step by the CMP method.

In the polishing by the CMP method, uneven portions on the surface of the substrate to be polished are planarized by supplying the polishing composition of the present disclosure to a contact part between the substrate to be polished and a polishing pad in a state where the surface of the substrate to be polished and the polishing pad are in contact with each other, and moving them relatively. In the production method of a semiconductor substrate of the present disclosure, another insulating film may be formed between the silicon dioxide layer of the silicon substrate and the polishing stopper film, or another insulating film may be formed between the film to be polished (e.g., silicon oxide film) and the polishing stopper film (e.g., silicon nitride film).

In the polishing step using the polishing composition of the present disclosure, for example, the number of revolutions of the polishing pad can be set to 30 to 200 r/min, the number of revolutions of the substrate to be polished can be set to 30 to 200 r/min, the polishing load of a polishing device equipped with the polishing pad can be set to 20 to 500 g weight/cm², and the supply rate of the polishing composition can be set to 10 to 500 mL/min. When the polishing composition is a two-pack type polishing composition, the polishing rates for the film to be polished and the polishing stopper film as well as the polishing rate ratio (polishing selectivity) between the film to be polished and the polishing stopper film can be adjusted by adjusting the supply rates (or supply amounts) of the first liquid and the second liquid.

In the polishing step using the polishing composition of the present disclosure, the polishing rate for the film to be polished (e.g., silicon oxide film) is preferably 2000 Å/min or more, more preferably 3000 Å/min or more, and further preferably 4000 Å/min or more from the viewpoint of improving the productivity.

In the polishing step using the polishing composition of the present disclosure, the polishing rate for the polishing stopper film (e.g., silicon nitride film) is preferably 500 Å/min or less, more preferably 300 Å/min or less, and further preferably 150 Å/min or less from the viewpoint of improving the polishing selectivity and shortening the polishing time.

In the polishing step using the polishing composition of the present disclosure, the polishing rate ratio (the polishing rate for the film to be polished/the polishing rate for the polishing stopper film) is preferably 5.0 or more, more preferably 10.0 or more, further preferably 20.0 or more, and still further preferably 40.0 or more from the viewpoint of shortening the polishing time. The term “polishing selectivity” in the present disclosure is synonymous with the ratio of the polishing rate for the film to be polished with respect to the polishing rate for the polishing stopper film (the polishing rate for the film to be polished/the polishing rate for the polishing stopper film). High polishing selectivity means a high polishing rate ratio.

[Polishing Method]

The present disclosure relates to a method for polishing a substrate, including a polishing step using the polishing composition of the present disclosure (hereinafter, also referred to as “polishing method of the present disclosure”).

The polishing method of the present disclosure can improve the polishing selectivity and reduce the polishing unevenness while increasing the polishing rate in the polishing step, thereby providing an effect of improving the productivity of a semiconductor substrate with improved substrate quality. The specific polishing method and polishing conditions can be the same as those described in the production method of a semiconductor substrate of the present disclosure.

The present disclosure further relates to the following compositions and production methods.

<1> A polishing composition, containing:

cerium oxide particles A;

an oligosaccharide B; and water,

wherein the oligosaccharide B contains a saccharide made up of 3 to 5 glucoses linked together, and in the oligosaccharide B, a content of a saccharide made up of 8 or more glucoses linked together is 27 mass % or less.

<2> The polishing composition according to <1>, wherein the average primary particle diameter of the particles A is preferably 5 nm or more, more preferably 10 nm or more, and further preferably 20 nm or more.

<3> The polishing composition according to <1> or <2>, wherein the average primary particle diameter of the particles A is preferably 300 nm or less, more preferably 200 nm or less, and further preferably 150 nm or less.

<4> The polishing composition according to any of <1> to <3>, wherein the content of the particles A in the polishing composition is preferably 0.05 mass % or more, more preferably 0.10 mass % or more, and further preferably 0.20 mass % or more when the total content of the particles A, the oligosaccharide B and water is assumed to be 100 mass %.

<5> The polishing composition according to any of <1> to <4>, wherein the content of the particles A in the polishing composition is preferably 10.0 mass % or less, more preferably 7.5 mass % or less, further preferably 5.0 mass % or less, still further preferably 2.5 mass % or less, and even further preferably 1.0 mass % or less when the total content of the particles A, the oligosaccharide B and water is assumed to be 100 mass %.

<6> The polishing composition according to any of <1> to <5>, wherein a constituent unit of the oligosaccharide B is glucose only.

<7> The polishing composition according to any of <1> to <6>, wherein the oligosaccharide B is at least one selected from gentiooligosaccharide, isomaltooligosaccharide, maltooligosaccharide, and nigerooligosaccharide.

<8> The polishing composition according to any of <1> to <7>, wherein the content of a saccharide having a molecular weight of 15,000 or more in the oligosaccharide B is 0 mass % or more.

<9> The polishing composition according to any of <1> to <8>, wherein the content of a saccharide having a molecular weight of 15,000 or more in the oligosaccharide B is preferably 10 mass % or less, more preferably 5 mass % or less, and further preferably 4 mass % or less.

<10> The polishing composition according to any of <1> to <9>, wherein the content of the oligosaccharide B is preferably 0.2 mass % or more, more preferably 0.3 mass % or more, further preferably 0.4 mass % or more, still further preferably 0.5 mass % or more, and even further preferably 0.8 mass % or more when the total content of the particles A, the oligosaccharide B and water is assumed to be 100 mass %.

<11> The polishing composition according to any of <1> to <10>, wherein the content of the oligosaccharide B is preferably 2.5 mass % or less, more preferably 2.0 mass % or less, further preferably 1.5 mass % or less, and still further preferably 1.1 mass % or less when the total content of the particles A, the oligosaccharide B and water is assumed to be 100 mass %.

<12> The polishing composition according to any of <1> to <11>, wherein the content of the oligosaccharide B is preferably 0.1 mass % or more and 2.5 mass % or less, more preferably 0.3 mass % or more and 2.5 mass % or less, further preferably 0.4 mass % or more and 2.0 mass % or less, and still further preferably 0.5 mass % or more and 1.5 mass % or less.

<13> The polishing composition according to any of <1> to <12>, wherein the content of the saccharide made up of 3 to 5 glucoses is preferably 0.05 mass % or more, more preferably 0.08 mass % or more, further preferably 0.10 mass % or more, still further preferably 0.12 mass % or more, yet further preferably 0.15 mass % or more, even further preferably 0.25 mass % or more, and still further preferably 0.35 mass % or more when the total content of the particles A, the oligosaccharide B and water is assumed to be 100 mass %.

<14> The polishing composition according to any of <1> to <13>, wherein the content of the saccharide made up of 3 to 5 glucoses is preferably 1.0 mass % or less, more preferably 0.7 mass % or less, and further preferably 0.5 mass % or less.

<15> The polishing composition according to any of <1> to <14>, wherein a ratio B/A of the content of the oligosaccharide B to the content of the particles A is preferably 0.01 or more, more preferably 0.1 or more, and further preferably 0.3 or more.

<16> The polishing composition according to any of <1> to <15>, wherein the ratio B/A of the content of the oligosaccharide B to the content of the particles A is preferably 20 or less, more preferably 10 or less, and further preferably 5 or less.

<17> The polishing composition according to any of <1> to <16>, wherein the ratio B/A of the content of the oligosaccharide B to the content of the particles A is 0.01 or more and 20 or less.

<18> The polishing composition according to any of <1> to <17>, wherein the weight average molecular weight of the oligosaccharide B is preferably less than 800, more preferably 750 or less, further preferably 700 or less, and still further preferably 600 or less.

<19> The polishing composition according to any of <1> to <18>, wherein the weight average molecular weight of the oligosaccharide B is preferably 300 or more, more preferably 350 or more, and further preferably 400 or more.

<20> The polishing composition according to any of <1> to <19>, further containing a compound C having an anionic group.

<21> The polishing composition according to <20>, wherein the weight average molecular weight of the compound C is preferably 1,000 or more, more preferably 10,000 or more, and further preferably 20,000 or more.

<22> The polishing composition according to <20> or <21>, wherein the weight average molecular weight of the compound C is preferably 5,500,000 or less, more preferably 1,000,000 or less, and further preferably 100,000 or less.

<23> The polishing composition according to <20>, wherein the compound C is a monovalent carboxylic acid.

<24> The polishing composition according to <23>, wherein the compound C is at least one selected from levulinic acid, propionic acid, vanillic acid, p-hydroxybenzoic acid, and formic acid.

<25> The polishing composition according to any of <20> to <24>, wherein the content of the compound C in the polishing composition is preferably 0.001 mass % or more, more preferably 0.0015 mass % or more, and further preferably 0.0025 mass % or more.

<26> The polishing composition according to any of <20> to <25>, wherein the content of the compound C in the polishing composition is preferably 1.0 mass % or less, more preferably 0.8 mass % or less, and further preferably 0.6 mass % or less.

<27> The polishing composition according to any of <20> to <26>, wherein a ratio (C/A) of the content of the compound C to the content of the particles A in the polishing composition is preferably 0.0001 or more, more preferably 0.0005 or more, and further preferably 0.001 or more.

<28> The polishing composition according to any of <20> to <27>, wherein the ratio (C/A) of the content of the compound C to the content of the particles A in the polishing composition is preferably 1 or less, more preferably 0.1 or less, and further preferably 0.01 or less.

<29> The polishing composition according to any of <1> to <28>, for use in polishing a silicon oxide film.

<30> The polishing composition according to any of <1> to <29>, wherein a pH of the polishing composition is preferably 4.0 or more, more preferably 5.0 or more, and further preferably 6.0 or more.

<31> The polishing composition according to any of <1> to <30>, wherein the pH of the polishing composition is preferably 9.0 or less, more preferably less than 9.0, further preferably 8.5 or less, and still further preferably 8.0 or less.

<32> The polishing composition according to any of <1> to <31>, wherein the pH of the polishing composition is 4.0 or more and less than 9.0.

<33> The polishing composition according to any of <1> to <32>, wherein the polishing composition is composed of a first liquid in which the particles A are mixed in water and a second liquid in which the oligosaccharide B is mixed in water, and the first liquid and the second liquid are mixed in use.

<34> A method for producing a semiconductor substrate, including polishing a substrate to be polished using the polishing composition according to any of <1> to <33>.

<35> A method for polishing a substrate, including polishing a substrate to be polished using the polishing composition according to any of <1> to <33>,

wherein the substrate to be polished is a substrate for producing a semiconductor substrate.

<36> A use of the polishing composition according to any of <1> to <33> for production of a semiconductor substrate.

### EXAMPLES

### 1. Preparation of Polishing Compositions (Examples 1-23 and Comparative Examples 1-20)

Water, abrasive grains (particles A), and additives (oligosaccharide B and compound C) were mixed in the proportion of Tables 1-1, 1-2 and 2 below to obtain polishing compositions of Examples 1-23 and Comparative Examples 1-20. The pH of the polishing compositions was adjusted using a 0.1 N ammonium aqueous solution.

The particles A used were colloidal ceria (“ZENUS HC90” manufactured by Solvay Special Chem Japan, Ltd. (previously Anan Kasei Co., Ltd.), average primary particle diameter: 99 nm, BET specific surface area: 8.4 m²/g), amorphous ceria (baked pulverized ceria GPL-C1010, manufactured by SHOWA DENKO K.K., average primary particle diameter: 70 nm, BET specific surface area: 11.8 m²/g), ceria-coated silica (average primary particle diameter: 92.5 nm, BET specific surface area: 35.5 m²/g) and cerium hydroxide (average primary particle diameter: 5 nm, BET specific surface area: 165 m²/g).

The compounds C used were ammonium polyacrylate (weight average molecular weight: 21,000), citric acid, levulinic acid, propionic acid, vanillic acid, p-hydroxybenzoic acid, and formic acid.

The oligosaccharides B (B1-B16) used were as follows. A main constituent unit refers to a monosaccharide having a degree of polymerization of 2 or more among the constituent units of the oligosaccharide, i.e., a monosaccharide serving as the constituent unit of a saccharide having a degree of polymerization of 2 or more in the oligosaccharide.

B1: Gentiooligosaccharide (trade name: Gentose (registered trademark) #45 manufactured by NIHON SHOKUHIN KAKO CO., LTD., constituent: linear oligosaccharide (monosaccharide to pentasaccharide), main constituent unit: glucose)

B2: Isomaltooligosaccharide (trade name: Biotose #50 manufactured by NIHON SHOKUHIN KAKO CO., LTD., constituent: branched oligosaccharide (trisaccharide to pentasaccharide), main constituent unit: glucose)

B3: Isomaltooligosaccharide (trade name: Nisshoku Branch-Oligo (registered tradename) manufactured by NIHON SHOKUHIN KAKO CO., LTD., constituent: branched oligosaccharide (trisaccharide to tetrasaccharide), main constituent unit: glucose)

B4: Maltooligosaccharid (trade name: Fuji-oligo (registered trademark) #450 manufactured by NIHON SHOKUHIN KAKO CO., LTD., constituent: linear oligosaccharide (disaccharide to decasaccharide), main constituent unit: glucose)

B5: Nigerooligosaccharide (trade name: Taste-oligo (registered trademark) manufactured by NIHON SHOKUHIN KAKO CO., LTD., constituent: linear oligosaccharide (monosaccharide to tetrasaccharide), main constituent unit: glucose)

B6: Glucose (monosaccharide)

B7: Galactose (monosaccharide)

B8: Xylitol (monosaccharide, sugar alcohol, no cyclic structure)

B9: D-Mannitol (monosaccharide, sugar alcohol, no cyclic structure)

B10: Sucrose (linear oligosaccharide (disaccharide), constituent unit: glucose+fructose)

B11: Trehalose (linear oligosaccharide (disaccharide), main constituent unit: glucose)

B12: Raffinose (linear oligosaccharide (trisaccharide), constituent unit: fructose+galactose+glucose)

B13: Galactooligosaccharide (linear oligosaccharide (disaccharide to pentasaccharide), main constituent unit: galactose)

B14: Sucrose stearate (trade name: S-970 manufactured by Mitsubishi-Chemical Foods Corporation, linear oligosaccharide (disaccharide), constituent unit: glucose+fructose)

B15: α-Cyclodextrin (cyclic oligosaccharide (hexasaccharide), main constituent unit: glucose)

B16: Chitinoligosaccharide (oligosaccharide made up of several N-acetylglucosamines linked together)

The pH of the polishing compositions, the average primary particle diameter and BET specific surface area of the particles A were measured by methods below. Tables 1-1, 1-2 and 2 show the results of the pH measurement.

(a) pH Measurement of Polishing Composition

The pH value of each polishing composition at 25° C. was measured using a pH meter (HM-30G manufactured by DKK-TOA CORPORATION) and was read on the pH meter one minute after dipping an electrode into the polishing composition.

(b) Average Primary Particle Diameter of Particles A

The average primary particle diameter (nm) of the particles A was calculated using a specific surface area S (m²/g) obtained by the following BET (nitrogen adsorption) method, with the true density of the ceria particles set as 7.2 g/cm³.

(c) Method for Measuring BET Specific Surface Area of Particles A

A dispersion liquid of the ceria particles A was dried with hot air at 120° C. for three hours and the resultant was pulverized in an agate mortar to obtain a sample. The sample obtained was dried immediately before measurement in an atmosphere at 120° C. for 15 minutes. Then, the specific surface area S (m²/g) was measured by the nitrogen adsorption (BET) method using a specific surface area measuring device (micromeritics automatic specific surface area measuring device, FlowSorb III 2305 manufactured by Shimadzu Corporation).

The constituents of the oligosaccharides B1-B16 were separated using HPLC under the following conditions and analyzed using LC-MS.

<Conditions of HPLC>
Column: Shodex Asahipak NH2P-50
Eluent: mixed solution of acetonitrile and water
Flow rate: 0.8 mL/min
Temperature: 30° C.
Sample concentration: 0.1% (solvent: mixed solution of acetonitrile and water)
Injected amount: 30 μL
Detection: Q-Exactive (FT-MS)

2. Evaluation of polishing compositions (Examples 1-23 and Comparative Examples 1-20)

[Production of Specimen]

A silicon oxide film having a thickness of 2000 nm was formed on one side of a silicon wafer by a TEOS-plasma CVD method, and a 40 mm×40 mm square piece was cut out from the silicon oxide film to prepare a specimen of the silicon oxide film.

Similarly, a silicon nitride film having a thickness of 300 nm was formed on one side of a silicon wafer by a CVD method, and a 40 mm×40 mm square piece was cut out from the silicon nitride film to prepare a specimen of the silicon nitride film.

[Measurement of Polishing Rate for Silicon Oxide Film (Film to be Polished)]

“MA-300” manufactured by Musashino Denshi Co., Ltd. (platen diameter: 300 mm) was used as a polishing device. A rigid urethane pad “IC-1000/Sub400” manufactured by Nitta Haas Incorporated was used as a polishing pad. The polishing pad was attached onto the platen of the polishing device. The specimen was set in a holder, and the holder was placed on the polishing pad so that the surface of the specimen on which the silicon oxide film was formed would face downward (so that the silicon oxide film would face the polishing pad). Further, a weight was placed on the holder so that a load applied to the specimen would be 300 g weight/cm². The specimen of the silicon oxide film was polished by rotating both of the platen and the holder in the same rotation direction at 90 r/min for one minute while dropping the polishing composition onto the center of the platen, on which the polishing pad was attached, at a rate of 50 mL/min. After polishing, the specimen was washed with ultrapure water and dried, followed by measurement using an optical interference-type film thickness measurement device described below.

The thicknesses of the silicon oxide film before and after polishing were measured using an optical interference-type film thickness measurement device (“Lambda Ace VM-1000” manufactured by SCREEN Semiconductor Solutions Co., Ltd.). The polishing rate for the silicon oxide film was calculated from the formula below. Tables 1-1, 1-2 and 2 show the results.

Polishing rate for silicon oxide film (Å/min)=[Thickness of silicon oxide film before polishing (Å)−Thickness of silicon oxide film after polishing (Å)]/Polishing time (min)

[Measurement of Polishing Rate for Silicon Nitride Film (Polishing Stopper Film)]

The polishing and thickness measurement of the silicon nitride film were performed in the same manner as in [Measurement of polishing rate for silicon oxide film] except for the use of the silicon nitride film instead of the silicon oxide film as a specimen. The polishing rate for the silicon nitride film was calculated from the formula below. Tables 1-1, 1-2 and 2 show the results.

Polishing rate for silicon nitride film (Å/min)=[Thickness of silicon nitride film before polishing (Å)−Thickness of silicon nitride film after polishing (Å)]/Polishing time (min)

[Polishing Rate Ratio]

The ratio of the polishing rate for the silicon oxide film with respect to the polishing rate for the silicon nitride film is defined as a polishing rate ratio, and calculated from the formula below. Tables 1-1, 1-2 and 2 show the results. The larger value of the polishing rate ratio indicates higher polishing selectivity.

Polishing rate ratio=Polishing rate for silicon oxide film (Å/min)/polishing rate for silicon nitride film (Å/min)

[Method for Evaluating Polishing Unevenness]

The following evaluation method was used to measure the number of unevenness on the specimen of the silicon nitride film after polishing. First, the specimen of the silicon nitride film was photographed using “COOLPIX S3700” manufactured by Nikon Corporation with the following settings.

ISO sensitivity: 400

Image mode: 2M (1600×1200)

White balance: Fluorescent

AF-area selection: Center

AF mode: AF-S single AF

AF-assist illuminator: Off

Electronic zoom: Off

Macro: ON

Using image analysis software WinROOF2013 manufactured by MITANI Corporation, the number of polishing unevenness in the photograph was measured under the following conditions.

The standard unit of measurement was set to 1 pixel. The photograph taken was monochromated, and a square area of 514×514 pixels inside the wafer was designated as an analysis area (hereinafter, referred to as a “designated area”) by trimming. Then, the 256-level gray scale of the inside of the designated area (actual area: 263952 pixels) was reversed to emphasize a portion where polishing unevenness was occurred for easy recognition of the polishing unevenness, and the emphasized portion was binarized with threshold of 80 to 184 and transparency of 127 using a function of the software of “Binarization with two thresholds”. Then, the shape features of the binary region were measured, and an uneven portion having different chromaticities was counted as the number of polishing unevenness. Tables 1-1, 1-2 and 2 show the measurement results.

[Evaluation of Stability]

The pH of the polishing compositions of Examples 15-23 after one month of still standing at 60° C. was measured. Table 2 shows the measurement results. The polishing composition that retained the polishing performance after one month of still standing can be judged as having favorable storage stability.

TABLE 1

| | Polishing composition | | | | | | | | | | | | | | |
|---|---|---|---|---|---|---|---|---|---|---|---|---|---|---|---|
| | | | Oligosaccharide B | | | | | | | | | | | | |
| | | | | | | Saccharide | Saccharide | | | | | | | | |
| | | | | | | made up of | made up of | | | | | Evaluation results | | | |
| | | | | | | 3 to 5 | 8 or more | | | | | | | Polishing | |
| | | | | | | glucose | glucose | | | | | | | rate ratio | |
| | | | | | | linked | linked | | | | | Polishing | Polishing | [silicon | |
| | | | | | | together | together | | | | | rate for | rate for | oxide | |
| | Cerium oxide | | | | | Content | Content | | Compound | | | silicon | silicon | film/ | |
| | particles A | | | | | (mass %) | (mass %) | | C | | | oxide | nitride | silicon | |
| | | Content | | | | [in oligo- | [in oligo- | Content | | Content | | film | film | nitride | Polishing |
| | Type | mass % | Type | | Constituent | saccharide B] | saccharide B] | mass % | Type | mass % | pH | [Å/min] | [Å/min] | film] | unevenness |
| Ex. 1 | Colloidal | 0.5 | B1 | Gentio- | Linear oligosaccharide | 27 | 0 | 1.0 | — | — | 6.0 | 7642 | 282 | 27 | 1 |
| | ceria | | | oligosaccharide | Main constituent unit: | | | | | | | | | | |
| | | | | | glucose | | | | | | | | | | |
| Ex. 2 | Colloidal | 0.5 | B1 | Gentio- | Linear oligosaccharide | 27 | 0 | 0.5 | — | — | 6.0 | 7628 | 314 | 24 | 1 |
| | ceria | | | oligosaccharide | Main constituent unit: | | | | | | | | | | |
| | | | | | glucose | | | | | | | | | | |
| Ex. 3 | Colloidal | 0.5 | B1 | Gentio- | Linear oligosaccharide | 27 | 0 | 1.5 | — | — | 6.0 | 7511 | 279 | 27 | 1 |
| | ceria | | | oligosaccharide | Main constituent unit: | | | | | | | | | | |
| | | | | | glucose | | | | | | | | | | |
| Ex. 4 | Colloidal | 0.5 | B2 | Isomalto- | Branched oligosaccharide | 43 | 0 | 1.0 | — | — | 6.0 | 7550 | 370 | 20 | 1 |
| | ceria | | | oligosaccharide | Main constituent unit: | | | | | | | | | | |
| | | | | | glucose | | | | | | | | | | |
| Ex. 5 | Colloidal | 0.5 | B3 | Isomalto- | Branched oligosaccharide | 74 | 25 | 1.0 | — | — | 6.0 | 7468 | 376 | 20 | 1 |
| | ceria | | | oligosaccharide | Main constituent unit: | | | | | | | | | | |
| | | | | | glucose | | | | | | | | | | |
| Ex. 6 | Colloidal | 0.5 | B4 | Malto- | Linear oligosaccharide | 75 | 0 | 1.0 | — | — | 6.0 | 6961 | 362 | 19 | 2 |
| | ceria | | | oligosaccharide | Main constituent unit: | | | | | | | | | | |
| | | | | | glucose | | | | | | | | | | |
| Ex. 7 | Colloidal | 0.5 | B5 | Nigero- | Linear oligosaccharide | 46 | 0 | 1.0 | — | — | 6.0 | 7457 | 332 | 22 | 1 |
| | ceria | | | oligosaccharide | Main constituent unit: | | | | | | | | | | |
| | | | | | glucose | | | | | | | | | | |
| Comp. | Colloidal | 0.5 | — | — | — | — | — | — | — | — | 6.0 | 7341 | 1570 | 5 | 0 |
| Ex. 1 | ceria | | | | | | | | | | | | | | |
| Comp. | Colloidal | 0.5 | B6 | Glucose | Monosaccharide | 0 | 0 | 1.0 | — | — | 6.0 | 6547 | 368 | 18 | 23 |
| Ex. 2 | ceria | | | | | | | | | | | | | | |
| Comp. | Colloidal | 0.5 | B7 | Galactose | Monosaccharide | 0 | 0 | 1.0 | — | — | 6.0 | 7304 | 505 | 14 | 33 |
| Ex. 3 | ceria | | | | | | | | | | | | | | |
| Comp. | Colloidal | 0.5 | B8 | Xylitol | Monosaccharide, | 0 | 0 | 1.0 | — | — | 6.0 | 7658 | 505 | 15 | 51 |
| Ex. 4 | ceria | | | | Sugar alcohol | | | | | | | | | | |
| | | | | | (no cyclic structure) | | | | | | | | | | |
| Comp. | Colloidal | 0.5 | B9 | D-Mannitol | Monosaccharide, | 0 | 0 | 1.0 | — | — | 6.0 | 7411 | 643 | 12 | 0 |
| Ex. 5 | ceria | | | | Sugar alcohol | | | | | | | | | | |
| | | | | | (no cyclic structure) | | | | | | | | | | |
| Comp. | Colloidal | 0.5 | B10 | Sucrose | Oligosaccharide | 0 | 0 | 1.0 | — | — | 6.0 | 6917 | 613 | 11 | 14 |
| Ex. 6 | ceria | | | | (disaccharide) | | | | | | | | | | |
| | | | | | Constituent unit: | | | | | | | | | | |
| | | | | | glucose + fructose | | | | | | | | | | |
| Comp. | Colloidal | 0.5 | B11 | Trehalose | Linear oligosaccharide | 0 | 0 | 1.0 | — | — | 6.0 | 8502 | 769 | 11 | 53 |
| Ex. 7 | ceria | | | | (disaccharide) | | | | | | | | | | |
| | | | | | Main constituent unit: | | | | | | | | | | |
| | | | | | glucose | | | | | | | | | | |
| Comp. | Colloidal | 0.5 | B12 | Raffinose | Linear oligosaccharide | 0 | 0 | 1.0 | — | — | 6.0 | 8699 | 409 | 21 | 13 |
| Ex. 8 | ceria | | | | (trisaccharide) | | | | | | | | | | |
| | | | | | Constituent unit: | | | | | | | | | | |
| | | | | | fructose + galactose + | | | | | | | | | | |
| | | | | | glucose | | | | | | | | | | |
| Comp. | Colloidal | 0.5 | B13 | Galacto- | Linear oligosaccharide | 0 | 0 | 1.0 | — | — | 6.0 | 8648 | 791 | 11 | 25 |
| Ex. 9 | ceria | | | oligosaccharide | (disaccharide to | | | | | | | | | | |
| | | | | | pentasaccharide) | | | | | | | | | | |
| | | | | | Main constituent unit: | | | | | | | | | | |
| | | | | | galactose | | | | | | | | | | |
| Comp. | Colloidal | 0.5 | B14 | Sucrose stearate | Linear oligosaccharide | 0 | 0 | 1.0 | — | — | 6.0 | 1172 | 235 | 5 | 2 |
| Ex. 10 | ceria | | | | (disaccharide) | | | | | | | | | | |
| | | | | | Constituent unit: | | | | | | | | | | |
| | | | | | glucose + fructose | | | | | | | | | | |
| Comp. | Colloidal | 0.5 | B15 | α-Cyclodextrin | Cyclic oligosaccharide | 0 | 0 | 1.0 | — | — | 6.0 | 6822 | 515 | 13 | 10 |
| Ex. 11 | ceria | | | | (hexasaccharide) | | | | | | | | | | |
| | | | | | Main constituent unit: | | | | | | | | | | |
| | | | | | glucose | | | | | | | | | | |
| Comp. | Colloidal | 0.5 | B16 | Chitin- | Oligosaccharide | 0 | 0 | 1.0 | — | — | 6.0 | 5201 | 1274 | 4 | 14 |
| Ex. 12 | ceria | | | oligosaccharide | made up of several | | | | | | | | | | |
| | | | | | N-acetylglucosamines | | | | | | | | | | |
| | | | | | linked together | | | | | | | | | | |
| Comp. | Cerium | 0.5 | B1 | Gentio- | Linear oligosaccharide | 27 | 0 | 1.0 | — | — | 6.0 | 372 | 98 | 4 | 0 |
| Ex. 13 | hydroxide | | | oligosaccharide | Main constituent unit: | | | | | | | | | | |
| | | | | | glucose | | | | | | | | | | |
| Comp. | Cerium | 0.5 | — | — | — | — | — | — | — | — | 6.0 | 3956 | 945 | 4 | 0 |
| Ex. 14 | hydroxide | | | | | | | | | | | | | | |
| Ex. 8 | Ceria- | 0.5 | B1 | Gentio- | Linear oligosaccharide | 27 | 0 | 1.0 | — | — | 6.0 | 3808 | 115 | 33 | 0 |
| | coated | | | oligosaccharide | Main constituent unit: | | | | | | | | | | |
| | silica | | | | glucose | | | | | | | | | | |
| Comp. | Ceria- | 0.5 | — | — | — | — | — | — | — | — | 6.0 | 3480 | 614 | 6 | 0 |
| Ex. 15 | coated | | | | | | | | | | | | | | |
| | silica | | | | | | | | | | | | | | |
| Ex. 14 | Amorphous | 0.5 | B1 | Gentio- | Linear oligosaccharide | 27 | 0 | 1.0 | — | — | 6.0 | 5904 | 271 | 22 | 1 |
| | ceria | | | oligosaccharide | Main constituent unit: | | | | | | | | | | |
| | | | | | glucose | | | | | | | | | | |
| Comp. | Amorphous | 0.5 | — | — | — | — | — | — | — | — | 6.0 | 6022 | 1597 | 4 | 1 |
| Ex. 20 | ceria | | | | | | | | | | | | | | |
| Ex. 9 | Colloidal | 0.5 | B1 | Gentio- | Linear oligosaccharide | 27 | 0 | 1.0 | — | — | 8.0 | 7036 | 222 | 32 | 0 |
| | ceria | | | oligosaccharide | Main constituent unit: | | | | | | | | | | |
| | | | | | glucose | | | | | | | | | | |
| Comp. | Colloidal | 0.5 | — | — | — | — | — | — | — | — | 8.0 | 6618 | 1498 | 4 | 0 |
| Ex. 16 | ceria | | | | | | | | | | | | | | |
| Ex. 10 | Colloidal | 0.5 | B1 | Gentio- | Linear oligosaccharide | 27 | 0 | 1.0 | Ammonium | 0.0015 | 8.0 | 4525 | 112 | 40 | 0 |
| | ceria | | | oligosaccharide | Main constituent unit: | | | | polyacrylate | | | | | | |
| | | | | | glucose | | | | | | | | | | |
| Ex. 11 | Colloidal | 0.5 | B1 | Gentio- | Linear oligosaccharide | 27 | 0 | 1.0 | Citric acid | 0.0015 | 8.0 | 3563 | 108 | 33 | 0 |
| | ceria | | | oligosaccharide | Main constituent unit: | | | | | | | | | | |
| | | | | | glucose | | | | | | | | | | |
| Comp. | Colloidal | 0.5 | — | — | — | — | — | — | Ammonium | 0.0015 | 8.0 | 3765 | 548 | 7 | 0 |
| Ex. 17 | ceria | | | | | | | | polyacrylate | | | | | | |
| Comp. | Cerium | 0.5 | B1 | Gentio- | Linear oligosaccharide | 27 | 0 | 1.0 | Ammonium | 0.0015 | 8.0 | 110 | 49 | 2 | 0 |
| Ex. 18 | hydroxide | | | oligosaccharide | Main constituent unit: | | | | polyacrylate | | | | | | |
| | | | | | glucose | | | | | | | | | | |
| Ex. 12 | Colloidal | 0.5 | B1 | Gentio- | Linear oligosaccharide | 27 | 0 | 1.0 | Ammonium | 0.0015 | 4.5 | 4409 | 104 | 42 | 0 |
| | ceria | | | oligosaccharide | Main constituent unit: | | | | polyacrylate | | | | | | |
| | | | | | glucose | | | | | | | | | | |
| Ex. 13 | Colloidal | 0.5 | B3 | Isomalto- | Branched oligosaccharide | 74 | 25 | 1.0 | Ammonium | 0.0015 | 4.5 | 5067 | 100 | 51 | 0 |
| | ceria | | | oligosaccharide | Main constituent unit: | | | | polyacrylate | | | | | | |
| | | | | | glucose | | | | | | | | | | |
| Comp. | Colloidal | 0.5 | — | — | — | — | — | — | Ammonium | 0.0015 | 4.5 | 4005 | 364 | 11 | 0 |
| Ex. 19 | ceria | | | | | | | | polyacrylate | | | | | | |

TABLE 2

| | Polishing composition | | | | | | | |
|---|---|---|---|---|---|---|---|---|
| | | | Oligosaccharide B | | | | | |
| | | | | | | Saccharide | Saccharide | |
| | | | | | | made | made | |
| | | | | | | up of | up of | |
| | | | | | | 3 to 5 | 8 or more | |
| | | | | | | glucose | glucose | |
| | | | | | | linked | linked | |
| | | | | | | together | together | |
| | Cerium oxide | | | | | Content | Content | |
| | particles A | | | | | (mass %) | (mass %) | |
| | | Content | | | | [in oligo- | [in oligo- | Content |
| | Type | mass % | Type | | Constituent | saccharide B] | saccharide B] | mass % |
| Ex. 15 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 16 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 17 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 18 | Amorphous | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 19 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 20 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 21 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 22 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |
| Ex. 23 | Colloidal | 0.5 | B1 | Gentio- | Linear oligosaccharide | 27 | 0 | 1.0 |
| | ceria | | | oligosaccharide | Main constituent | | | |
| | | | | | monosaccharide: glucose | | | |

| | | | | Evaluation results | | | | | |
|---|---|---|---|---|---|---|---|---|---|
| | | | | | | Polishing | | | |
| | | | | Polishing | Polishing | rate ratio | | Stability | |
| | Polishing composition | | | rate for | rate for | [silicon | | 60° C. | |
| | Compound | | | silicon | silicon | oxide film/ | | | After |
| | C | | | oxide | nitride | silicon | | | lapse |
| | | Content | | film | film | nitride | Polishing | Initial | of one |
| | Type | mass % | pH | [Å/min] | [Å/min] | film] | unevenness | stage | month |
| Ex. 15 | — | — | 4.5 | 7375 | 298 | 25 | 0 | 4.5 | 3.7 |
| Ex. 16 | Levulinic acid | 0.001 | 4.5 | 7462 | 273 | 27 | 0 | 4.5 | 4.0 |
| Ex. 17 | Levulinic acid | 0.01 | 4.5 | 6874 | 243 | 28 | 0 | 4.5 | 4.2 |
| Ex. 18 | Levulinic acid | 0.01 | 4.5 | 5209 | 223 | 23 | 0 | 4.5 | 4.2 |
| Ex. 19 | Levulinic acid | 0.1 | 4.5 | 4663 | 285 | 16 | 0 | 4.5 | 4.4 |
| Ex. 20 | Propionic acid | 0.01 | 4.5 | 6693 | 334 | 20 | 0 | 4.5 | 4.2 |
| Ex. 21 | Vanillic acid | 0.01 | 4.5 | 6941 | 335 | 21 | 0 | 4.5 | 4.2 |
| Ex. 22 | P- | 0.01 | 4.5 | 8367 | 389 | 22 | 0 | 4.5 | 4.2 |
| | Hydroxybenzoic | | | | | | | | |
| | acid | | | | | | | | |
| Ex. 23 | Formic acid | 0.01 | 4.5 | 6864 | 274 | 25 | 0 | 4.5 | 4.2 |

As shown in Tables 1-1, 1-2 and 2, the polishing compositions of Examples 1-23 containing a predetermined oligosaccharide B improved the polishing selectivity and reduced the polishing unevenness while increasing the polishing rate. The polishing compositions of Examples 10-13 containing ammonium polyacrylate or citric acid as the compound C further improved the polishing selectivity. The polishing compositions of Examples 16-23 containing levulinic acid, propionic acid, vanillic acid, p-hydroxybenzoic acid, or formic acid as the compound C had favorable storage stability.

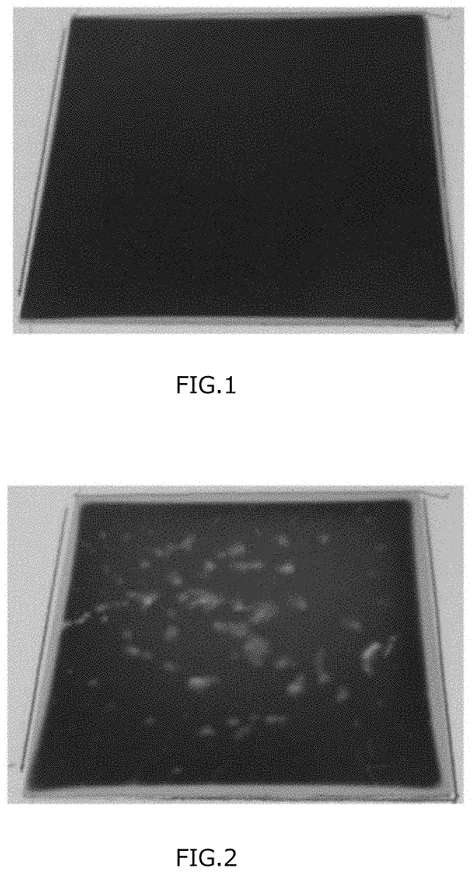

Moreover, FIGS. 1 and 2 respectively show the observation image of the surface of the silicon nitride film polished using the polishing composition of Example 1 and the polishing composition of Comparative Example 4. As shown in FIG. 1, no polishing unevenness was visually observed on the surface of the silicon nitride film polished using the polishing composition of Example 1. On the other hand, as shown in FIG. 2, polishing unevenness was visually observed on the surface of the silicon nitride film polished using the polishing composition of Comparative Example 4.

### INDUSTRIAL APPLICABILITY

The polishing composition of the present disclosure is useful in a method for producing a high density or high integration semiconductor substrate.

1. A polishing composition, comprising:
cerium oxide particles A;
an oligosaccharide B; and
water,
wherein the oligosaccharide B comprises a saccharide made up of 3 to 5 glucoses linked together, and
in the oligosaccharide B, a content of a saccharide made up of 8 or more glucoses linked together is 27 mass % or less.

2. The polishing composition according to claim 1, wherein a constituent unit of the oligosaccharide B is glucose only.

3. The polishing composition according to claim 1, for use in polishing a silicon oxide film.

4. The polishing composition according to claim 1, wherein the oligosaccharide B is at least one selected from gentiooligosaccharide, isomaltooligosaccharide, maltooligosaccharide, and nigerooligosaccharide.

5. The polishing composition according to claim 1, wherein a content of the oligosaccharide B is 0.1 mass % or more and 2.5 mass % or less.

6. The polishing composition according to claim 1, wherein a ratio B/A of the content of the oligosaccharide B to a content of the cerium oxide particles A is 0.01 or more and 20 or less.

7. The polishing composition according to claim 1, further comprising a compound C having an anionic group.

8. The polishing composition according to claim 7, wherein the compound C is a monovalent carboxylic acid.

9. The polishing composition according to claim 8, wherein the compound C is at least one selected from levulinic acid, propionic acid, vanillic acid, p-hydroxybenzoic acid, and formic acid.

10. The polishing composition according to claim 1, wherein a pH of the polishing composition is 4.0 or more and less than 9.0.

11. The polishing composition according to claim 1, wherein the polishing composition is composed of a first liquid in which the cerium oxide particles A are mixed in water and a second liquid in which the oligosaccharide B is mixed in water, and the first liquid and the second liquid are mixed in use.

12. A method for producing a semiconductor substrate, comprising polishing a substrate to be polished using the polishing composition according to claim 1.

13. A method for polishing a substrate, comprising polishing a substrate to be polished using the polishing composition according to claim 1,
wherein the substrate to be polished is a substrate for producing a semiconductor substrate.

14. (canceled)
